(19) United States
(12) Patent Application Publication
(10) Pub. No.: US 2025/0248182 A1
(43) Pub. Date: Jul. 31, 2025

(54) LIGHT-EMITTING DEVICE

(71) Applicant: Stanley Electric Co., Ltd., Tokyo (JP)

(72) Inventors: Takumi IKEDA, Tokyo-to (JP); Takashi AKINO, Tokyo-to (JP); Masaru KURAMOTO, Tokyo-to (JP)

(73) Assignee: Stanley Electric Co., Ltd., Tokyo (JP)

(21) Appl. No.: 19/035,978

(22) Filed: Jan. 24, 2025

(30) Foreign Application Priority Data
Jan. 25, 2024 (JP) 2024-009301

(51) Int. Cl. H10H 20/855; H10H 20/851

(52) U.S. Cl. CPC H10H 20/855; H10H 20/8512

(57) ABSTRACT

Provided is a light-emitting device capable of improving an extraction efficiency of an emitted light. The light-emitting device includes a light-emitting element, a phosphor layer, a translucent light-transmitting layer, and a wire grid portion. The light-emitting element includes a semiconductor structure layer with a light-emitting layer. The phosphor layer is formed on the light-emitting element and contains a fluorescent substance. The fluorescent substance is excited by a light emitted from the light-emitting layer to emit a fluorescent light. The light-transmitting layer is formed on the phosphor layer and has a side surface inclined outward toward an upper side. The wire grid portion is formed on the light-transmitting layer and includes a translucent light-transmitting substrate and a wire grid. The wire grid includes a plurality of linear metal bodies periodically arranged in a row on an upper surface of the light-transmitting substrate.

### CROSS-REFERENCE TO RELATED APPLICATION

The present application is based upon and claims the benefit of priority from the prior Japanese Patent Application No. 2024-009301 filed on Jan. 25, 2024, the entire contents of which are incorporated herein by reference.

### BACKGROUND

### 1. Technical Field

The present invention relates to a light-emitting device that includes a light-emitting element.

### 2. Description of the Related Art

There has been disclosed a light-emitting device including a polarizing layer that transmits a specific light. For example, JP-T-2011-501460 discloses a light-emitting device that includes a light-emitting element (LED die), a phosphor layer formed on one principal surface of the light-emitting element, a light polarizing layer configured of a wire grid formed on the phosphor layer, and a light reflecting layer formed on another principal surface of the light-emitting element.

### SUMMARY

In the light-emitting device disclosed in JP-T-2011-501460, in a light that has reached the light polarizing layer, a polarization component having a vibration direction perpendicular to a longitudinal direction of the wire grid passes through the light polarizing layer, and a polarization component parallel to the longitudinal direction is reflected by the light polarizing layer. Additionally, even in the polarization component having the vibration direction perpendicular to the longitudinal direction of the wire grid, a component incident on the light polarizing layer from the phosphor layer with an angle exceeding a critical angle is totally reflected.

In the light-emitting device disclosed in JP-T-2011-501460, for example, the component reflected by the light polarizing layer as described above is reflected by the light reflecting layer, thereby being allowed to be incident on the light polarizing layer again. However, even when the light is reflected by the light polarizing layer, a part of it is absorbed by the light polarizing layer, therefore, the more repeatedly the light is reflected between the light polarizing layer and the light reflecting layer, the more the extraction efficiency of the light extracted as a whole of the light-emitting device is possibly reduced.

The present invention is made in consideration of the above-described point, and an object of the present invention is to provide a light-emitting device capable of improving an extraction efficiency of an emitted light.

A light-emitting device according to the present invention includes a light-emitting element, a phosphor layer, a translucent light-transmitting layer, and a wire grid portion. The light-emitting element includes a semiconductor structure layer with a light-emitting layer. The phosphor layer is formed on the light-emitting element and contains a fluorescent substance. The fluorescent substance is excited by a light emitted from the light-emitting layer to emit a fluorescent light. The light-transmitting layer is formed on the phosphor layer and has a side surface inclined outward toward an upper side. The wire grid portion is formed on the light-transmitting layer and includes a translucent light-transmitting substrate and a wire grid. The wire grid includes a plurality of linear metal bodies periodically arranged in a row on an upper surface of the light-transmitting substrate.

### BRIEF DESCRIPTION OF THE DRAWINGS

FIG. 1 is a top view of a light-emitting device according to Embodiment 1;

FIG. 2 is a cross-sectional view of the light-emitting device according to Embodiment 1;

FIG. 3 is a drawing schematically illustrating a refractive index distribution of a light-transmitting layer;

FIG. 4 is a cross-sectional view illustrating a simulation model for validation of the light-emitting device according to Embodiment 1;

FIG. 5 is a graph illustrating a ratio of light flux with respect to an angle between an upper surface and a side surface of a light-transmitting layer in the simulation model;

FIG. 6 is a graph illustrating the ratio of light flux with respect to the angle between the upper surface and the side surface of the light-transmitting layer in the simulation model;

FIG. 7 is a graph illustrating the ratio of light flux with respect to the angle between the upper surface and the side surface of the light-transmitting layer in the simulation model; and

FIG. 8 is a cross-sectional view illustrating a modification of the simulation model.

### DETAILED DESCRIPTION

The following describes embodiments of the present invention in detail. Note that the same reference numerals are given to substantially identical or equivalent parts in the following description and the accompanying drawings.

### Embodiment 1

### Outline of Light-Emitting Device 100

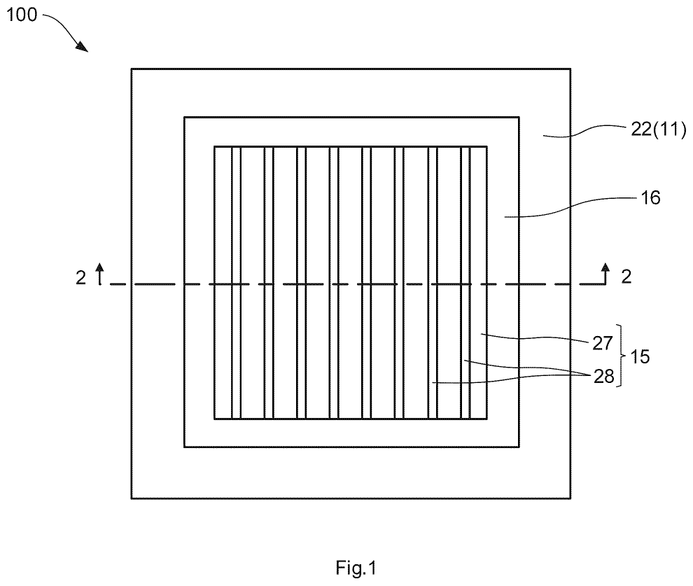

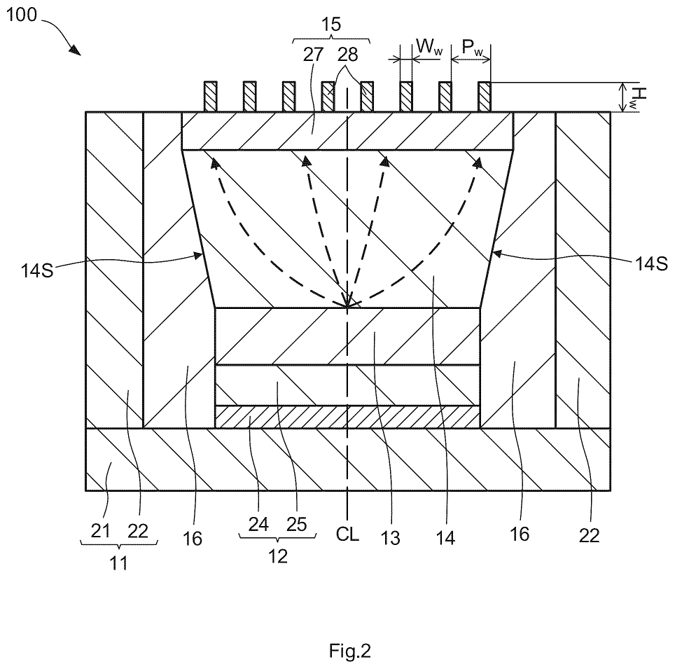

A configuration of a light-emitting device 100 according to Embodiment 1 is described with reference to FIG. 1 and FIG. 2. FIG. 1 is a top view of the light-emitting device 100 according to Embodiment 1. FIG. 2 is a cross-sectional view of the light-emitting device 100 illustrated in FIG. 1 taken along the line 2-2.

The light-emitting device 100 is configured to include a substrate structure 11, a light-emitting element 12, a phosphor layer 13, a light-transmitting layer 14, a wire grid portion 15, and a covering member 16. In FIG. 2, an up-down direction in the drawing is a height direction of the light-emitting device 100, and a right-left direction in the drawing is a width direction of the light-emitting device 100. In FIG. 2, a center axis CL passing through the center of the upper surface when the light-emitting device 100 is viewed from above is indicated by the two-dot chain line.

### Substrate Structure 11

First, the configuration of the substrate structure 11 is described. The substrate structure 11 includes a flat plate-shaped flat plate portion 21 having a rectangular upper surface shape and a frame-shaped frame body portion 22 formed along an outer edge of the upper surface of the flat plate portion 21.

That is, the substrate structure 11 is a recessed structure configured to expose the upper surface of the flat plate portion 21 by the frame body portion 22. The substrate structure 11 is made of, for example, a material having an electrical insulating property and a light reflectivity, such as aluminum oxide (Al₂O₃).

### Light-Emitting Element 12

Next, the configuration of the light-emitting element 12 is described. The light-emitting element 12 is an LED (Light Emission Diode) having a rectangular upper surface shape disposed on the upper surface of the flat plate portion 21. The light-emitting element 12 is configured to include a semiconductor structure layer 24 and a transparent substrate 25.

The semiconductor structure layer 24 is a semiconductor stacked body that includes an n-type semiconductor layer, a light-emitting layer, and a p-type semiconductor layer (none is illustrated) each containing gallium nitride (GaN) as a main material. When the light-emitting device 100 is driven, a blue light having a peak wavelength of about 450 nm is emitted from the light-emitting layer of the semiconductor structure layer 24.

The transparent substrate 25 is a flat plate-shaped substrate disposed on the semiconductor structure layer 24. The transparent substrate 25 is made of a material having a translucency to the blue light emitted from the light-emitting layer of the semiconductor structure layer 24, for example, sapphire (Al₂O₃). The transparent substrate 25 is also a growth substrate that grows a semiconductor crystal to be the semiconductor structure layer 24.

In the light-emitting device 100, the light-emitting element 12 includes an n-electrode and a p-electrode (not illustrated) connected to the n-type semiconductor layer and the p-type semiconductor layer of the semiconductor structure layer 24, respectively, and the n-electrode and the p-electrode are electrically connected to respective wiring pads (not illustrated) formed on the upper surface of the flat plate portion 21. That is, in the light-emitting device 100, the light-emitting element 12 is flip-chip mounted on the flat plate portion 21.

### Phosphor Layer 13

Next, the phosphor layer 13 is described. The phosphor layer 13 is a plate-shaped body having a rectangular upper surface shape disposed on the upper surface of the transparent substrate 25 of the light-emitting element 12. The phosphor layer 13 has the same size as the light-emitting element 12 in plan view when the phosphor layer 13 is viewed from above.

The phosphor layer 13 is formed of a fluorescent substance that is excited by the blue light as an excitation light emitted from the light-emitting element 12 and emits a fluorescent light. The fluorescent light emitted from the fluorescent substance when excited by the blue light has a broad wavelength range of green to orange from 480 to 700 nm, and has a peak wavelength of yellow in 520 to 570 nm.

The phosphor layer 13 is, for example, a ceramic phosphor plate that contains alumina (Al₂O₃) or silicon dioxide (SiO₂) containing phosphor particles of yttrium aluminum garnet activated with cerium (Ce) (YAG:Ce) as a medium.

The phosphor layer 13 is not limited to the phosphor plate configured to contain the YAG:Ce phosphor particles. For example, a phosphor plate that contains YAG, which is a base material of the phosphor particles, as a medium may be used. In this case, the phosphor layer 13 may be a polycrystalline material, or may be a single-crystalline material. For example, the phosphor layer 13 also can be configured by dispersing the phosphor particles of YAG:Ce or the like in a translucent resin, such as a silicone resin.

When the excitation light (blue light) emitted from the light-emitting element 12 is incident on the phosphor layer 13, a part of it directly passes through the phosphor layer 13, and a part of it excites the fluorescent substance to emit a fluorescent light from the excited fluorescent substance. Therefore, the excitation light that has passed through the phosphor layer 13 without a contribution to the fluorescent light generation and the fluorescent light emitted from the fluorescent substance are emitted from the upper surface of the phosphor layer 13.

### Light-Transmitting Layer 14

Next, the light-transmitting layer 14 is described. The light-transmitting layer 14 is a light-transmitting body that is disposed on the upper surface of the phosphor layer 13 and has a shape of inverted truncated quadrangular pyramid. In other words, the light-transmitting layer 14 has side surfaces 14S each inclined outward from the upper surface of the phosphor layer 13 toward the upper side. In the light-emitting device 100, the light-transmitting layer 14 is a GRIN (Gradient Index) lens that has a refractive index continuously changed inside.

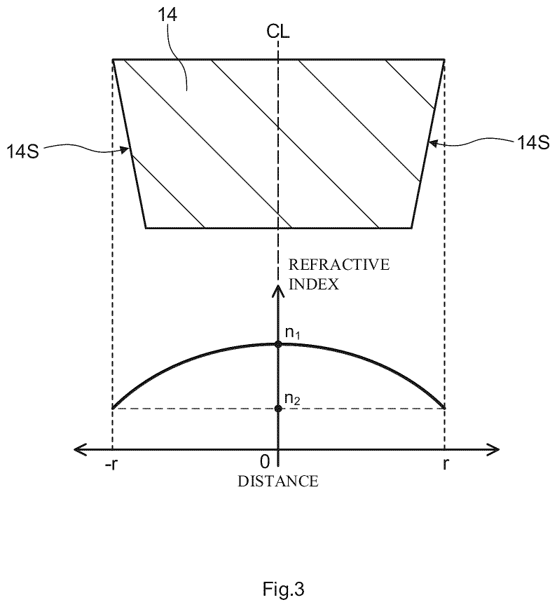

Here, a refractive index distribution of the light-transmitting layer 14 is described using FIG. 3. FIG. 3 is a graph schematically illustrating the light-transmitting layer 14 extracted alone from FIG. 2 and the refractive index distribution of the light-transmitting layer 14 in a width direction.

The graph illustrated in FIG. 3 has a horizontal axis indicating a distance from the center axis CL passing through the light-transmitting layer 14, that is, a distance in the width direction of the light-transmitting layer 14 from a point on the center axis CL, and a vertical axis indicating the refractive index inside the light-transmitting layer 14. In the following description, the light-transmitting layer 14 is assumed to have a shape of an inverted truncated square pyramid.

In the light-emitting device 100, as illustrated in FIG. 3, the refractive index of the light-transmitting layer 14 becomes highest at a portion passing through the center axis CL, and the refractive index decreases toward the side surface 14S from the center axis CL, that is, as the distance from the center axis CL becomes large. Therefore, in the light-transmitting layer 14, the refractive index becomes minimum at the outer edge of the upper surface. Note that in the light-transmitting layer 14, the refractive index in the up-down direction of the drawing, that is, the refractive index from the upper surface to the lower surface of the light-transmitting layer 14 is same.

Here, when the maximum refractive index of the light-transmitting layer 14 is defined as a maximum refractive index n₁, the minimum refractive index of the light-transmitting layer 14 is defined as a minimum refractive index n₂, and the refractive index at a position apart from the center of the light-transmitting layer 14 in the width direction by r is defined as a refractive index n(r), the refractive index n(r) is indicated by a formula 1 below using the refractive index n₁. However, √A is a gradient coefficient.

$$n ( r ) = {n}_{1} ( 1 - \frac{{( r \sqrt{A} )}^{2}}{2} ) \qquad [ Math . 1 ]$$

At this time, when a length of one side of the upper surface of the light-transmitting layer 14 is defined as a length D, the minimum refractive index n₂ is indicated by a formula 2 below because the longest distance from the center axis CL is a half of the length of the diagonal line of the square (√2D/2). The length D is indicated by a formula 3 below derived from the formula 2.

$${n}_{2} = {n}_{1} ( 1 - \frac{{( \frac{\sqrt{2}}{2} D \sqrt{A} )}^{2}}{2} ) \qquad [ Math . 2 ]$$

$$D = \frac{\sqrt[2]{1 - \frac{{n}_{2}}{{n}_{1}}}}{\sqrt{A}} \qquad [ Math . 3 ]$$

When a lens pitch of the light-transmitting layer 14 is defined as a pitch P, and a thickness of the light-transmitting layer 14 is defined as a thickness T, a relation between the pitch P and the thickness T is indicated by a formula 4 below. Therefore, the gradient coefficient √A is indicated by a formula 5 derived from the formula 4.

$$2 π P = \sqrt{A} T \qquad [ Math . 4 ]$$

$$\sqrt{A} = \frac{2 π P}{T} \qquad [ Math . 5 ]$$

In the light-emitting device 100 of this embodiment, the maximum refractive index n₁ of the light-transmitting layer 14 is larger than the refractive index of the phosphor layer 13, and the minimum refractive index n₂ of the light-transmitting layer 14 is smaller than the refractive index of the phosphor layer 13.

The light-transmitting layer 14 is made of a glass having a translucency to the blue light emitted from the light-emitting element 12 and the yellow fluorescent light emitted from the phosphor layer 13. The light-transmitting layer 14 is, for example, manufactured by forming a refractive index distribution in a radial direction in a column-shaped rod made of a glass by an ion-exchange process, and processing the rod after the formation of the refractive index distribution in a truncated quadrangular pyramid shape.

### Wire Grid Portion 15

With reference to FIG. 2 again, the configuration of the wire grid portion 15 is described. The wire grid portion 15 is configured to include a light-transmitting substrate 27 and a wire grid 28.

The light-transmitting substrate 27 is a flat plate-shaped substrate having a rectangular upper surface shape disposed on the upper surface of the light-transmitting layer 14. The light-transmitting substrate 27 has the same size as the upper surface of the light-transmitting layer 14 in top view. The light-transmitting substrate 27 is made of a material, for example, a glass having a translucency to the blue light and the yellow fluorescent light.

In the light-emitting device 100 of this embodiment, the light-transmitting substrate 27 has a refractive index smaller than the maximum refractive index n₁ and equal to or more than the minimum refractive index n₂ of the light-transmitting layer 14. The refractive index of the light-transmitting substrate 27 is smaller than the refractive index of the phosphor layer 13.

The wire grid 28 is configured to include a plurality of linear metal bodies arranged in a row on the upper surface of the light-transmitting substrate 27. In the wire grid 28, as illustrated in FIG. 1, each of the metal bodies extends from one side to the other side of mutually opposing two sides on the upper surface of the light-transmitting substrate 27. The wire grid 28 is made of, for example, aluminum (Al).

In the wire grid 28, the respective metal bodies are arranged at pitches P_{w} shorter than wavelengths of the blue light and the yellow fluorescent light on the upper surface of the light-transmitting substrate 27. The pitch P_{w} is, for example, 150 nm. For example, a width W_{w} between the metal bodies is 60 nm, and a height H_{w} of each of the metal bodies is 165 nm.

In the wire grid 28, with the pitch P_{w} set as described above, a TM polarization as a component having an electric field vector perpendicular to a longitudinal direction of the wire grid 28 of the blue light and the yellow fluorescent light passes through the wire grid 28, and a TE polarization as a component having an electric field vector parallel to the longitudinal direction of the blue light and the yellow fluorescent light is reflected by the wire grid 28. That is, the wire grid portion 15 functions as a polarizing layer that transmits only the lights vibrating only in a specific direction and reflects lights vibrating in other directions.

The wire grid 28 can be formed by, for example, forming a metal film of Al on the entire upper surface of the light-transmitting substrate 27 by ion beam deposition, forming a resist mask at an area to be the wire grid 28 on the upper surface, and then removing the metal film at an area without the mask by dry etching.

### Covering Member 16

Next, the configuration of the covering member 16 is described. The covering member 16 is a resin member that continuously covers a side surface of the light-emitting element 12, a side surface of the phosphor layer 13, and a side surface of the light-transmitting substrate 27 of the wire grid portion 15.

The covering member 16 is configured to contain, for example, a translucent silicone resin as a matrix material and white titanium dioxide (TiO₂) particles as light scattering particles dispersed in the matrix material.

The covering member 16 having the above-described configuration reflects a light in a visible light band incident on the covering member 16. Therefore, the covering member 16 reflects the blue light emitted from the light-emitting element 12 and the yellow light emitted from the phosphor layer 13.

### Improvement of Extraction Efficiency of Emitted Light

Here, with reference to FIG. 2, the improvement of extraction efficiency of the light emitted from the light-emitting device 100 is described.

As described above, in the wire grid portion 15, the TM polarization as a component having an electric field vector perpendicular to the longitudinal direction of the wire grid 28 of the light incident on the wire grid portion 15 passes through the wire grid 28, and the TE polarization as a component having an electric field vector parallel to the longitudinal direction of the light incident on the wire grid portion 15 is reflected by the wire grid 28.

At this time, for example, a fluorescent component incident on the wire grid portion 15 with an angle exceeding a critical angle of the fluorescent light emitted from the phosphor layer 13 is totally reflected by the wire grid portion 15 even when it is a TM polarization.

The TM polarization reflected by the wire grid portion 15 is reflected by, for example, the upper surface of the phosphor layer 13 and the upper surface of the flat plate portion 21, and this changes the incident angle at the incident on the wire grid portion 15 again.

For example, the TM polarization reflected by the upper surface of the phosphor layer 13 passes through the wire grid portion 15 when the incident angle to the wire grid portion 15 is equal to or less than the critical angle, and in the other case, the TM polarization is repeatedly reflected between the wire grid portion 15 and the phosphor layer 13 until the incident angle becomes equal to or less than the critical angle.

The fluorescent light emitted from the phosphor layer 13 is partially absorbed by the wire grid portion 15 when incident on the wire grid portion 15 once. Therefore, even when the TM polarization is repeatedly reflected between the wire grid portion 15 and the phosphor layer 13 and then passes through the wire grid portion 15, the light flux thereof is small compared with the light flux of the TM polarization that has passed through the wire grid portion 15 without being reflected even once.

Accordingly, for example, when there are many components exceeding the critical angle in the TM polarization of the fluorescent light incident on the wire grid portion 15, even when the TM polarization passes through the wire grid portion 15 after the repeated reflection, the light flux obtained as a whole is small. That is, the extraction efficiency of the light extracted from the light-emitting device 100 is possibly reduced.

In the light-emitting device 100 of the embodiment, as described above, the refractive index of the light-transmitting layer 14 decreases from the center axis CL toward the side surface 14S. Therefore, for example, the fluorescent light emitted from the phosphor layer 13 and incident on the center of the lower surface of the light-transmitting layer 14 is refracted so as to curve toward the upper surface of the light-transmitting layer 14 as the fluorescent light approaches the side surface 14S from the center axis CL of the light-transmitting layer 14 as indicated by dashed arrows of FIG. 2.

Accordingly, in the light-emitting device 100, the larger the emitted angle of the fluorescent component with respect to the center axis CL is, that is, the larger the incident angle of the fluorescent component at the incident on the wire grid portion 15 can become, the more the fluorescent component is refracted to bend within the light-transmitting layer 14.

Accordingly, in the light-emitting device 100 of the embodiment, even the TM polarization exceeding the critical angle when emitted from the phosphor layer 13 is easily reduced to equal to or less than the critical angle by being refracted inside the light-transmitting layer 14. That is, according to the light-emitting device 100 of the embodiment, providing the light-transmitting layer 14 allows reducing the fluorescent component reflected by the wire grid portion 15.

Accordingly, the light-emitting device 100 of the embodiment can increase the fluorescent component emitted from the phosphor layer 13 and passing through the wire grid portion 15. Therefore, the extraction efficiency of the emitted light can be improved compared with, for example, a light-emitting device that includes a light-transmitting layer 14 without the above-described refractive index distribution.

In the light-emitting device 100 of the embodiment, as described above, the side surface 14S is inclined outward toward the upper side of the light-transmitting layer 14. With the side surface 14S thus inclined outward, the light-emitting device 100 can provide the high light extraction efficiency compared with a light-emitting device with a side surface 14S perpendicular to the upper surface of the phosphor layer 13.

Specifically, in the light-emitting device 100 of the embodiment, for example, the side surface 14S inclined outward increases the distance from the center of the light-transmitting layer 14 to the side surface 14S compared with the case where the side surface 14S is perpendicular to the upper surface of the phosphor layer 13. Therefore, in the light-emitting device 100 of the embodiment, for example, a light from the center toward the side portion of the light-transmitting layer 14 is easily traveled upward before reaching the side surface 14S by the refractive index distribution as illustrated in FIG. 2. In other words, in the light-emitting device 100, the light is less likely to be reflected by the side surface 14S due to the refractive index distribution of the light-transmitting layer 14.

Here, the light reflected by the side surface 14S travels from a side small in refractive index distribution to a side large in refractive index distribution inside the light-transmitting layer 14, and this is a cause of reduction of the light extraction efficiency in the light-emitting device 100. Therefore, it is preferred to suppress the reflection of the light by the side surface 14S as much as possible.

In the light-emitting device 100 of the embodiment, with the side surface 14S inclined outward, the light from the center toward the side portion of the light-transmitting layer 14 is easily incident on the light-transmitting substrate 27 before reaching the side surface 14S. Therefore, for example, compared with the case where the side surface 14S is perpendicular to the upper surface of the phosphor layer 13, the high light extraction efficiency can be provided.

Even when the fluorescent light emitted from the phosphor layer 13 and traveling the light-transmitting layer 14 reaches the side surface 14S, since the fluorescent light is easily reflected upward by the side surface 14S, for example, the fluorescent component less than the critical angle can be changed to the fluorescent component equal to or less than the critical angle. Therefore, the light-emitting device 100 of the embodiment can increase the fluorescent component traveling toward the wire grid portion 15.

Therefore, according to the light-emitting device 100 of the embodiment, since the side surface 14S is inclined outward toward the upper side of the light-transmitting layer 14, the extraction efficiency of the emitted light can be improved, for example, compared with a light-emitting device in which the side surface 14S is perpendicular to the upper surface of the phosphor layer 13.

While the light-emitting device 100 of the embodiment is provided with the side surface 14S inclined outward toward the upper side of the light-transmitting layer 14 and the internal refractive index that continuously changes, only any one of them may be provided. That is, it is only necessary that the light-transmitting layer 14 includes the side surface 14S inclined outward, or it is only necessary that the above-described refractive index distribution is internally provided.

In the light-emitting device 100 of the embodiment, while the light-transmitting layer 14 is described to have the shape of inverted truncated quadrangular pyramid, the shape is not limited thereto. For example, when the upper surface of the light-emitting element 12 has a circular shape, the light-transmitting layer 14 may have a shape of inverted truncated cone corresponding to the shape of the light-emitting element 12.

In the light-emitting device 100 of the embodiment, the refractive indexes and the refractive index distribution of the light-transmitting layer 14, the phosphor layer 13, and the light-transmitting substrate 27 can be measured using an appropriate method, for example, minimum deviation method and spectroscopic ellipsometry. A magnitude relation of the refractive index between the light-transmitting layer 14, the phosphor layer 13, and the light-transmitting substrate 27 can be evaluated with the refractive indexes at a specific wavelength included in the wavelength band of the light emitted from the upper surface of the phosphor layer 13.

In the light-emitting device 100 of the embodiment, the wire grid 28 may be provided with a cover film to protect the surface thereof. For example, on the upper surface of the light-transmitting substrate 27 and the surface of the wire grid 28, a cover film made of zirconium oxide (ZrO₂) or silicon oxide (SiO₂) may be formed by ALD (Atomic Layer Deposition) method, sputtering method, CVD method, and the like.

### Validation

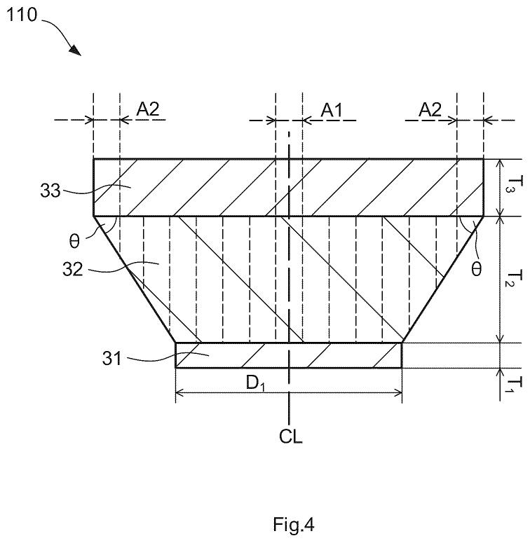

The following describes a validation performed on a model of the light-emitting device 100 of the embodiment and a model of a comparative example and verification results thereof with respect to FIG. 4 to FIG. 7. In the validation, light fluxes of the respective models and a preferable range of an angle between the upper surface and the side surface of the light-transmitting layer were verified. In this validation, Light Tools (manufactured by Synopsys) that is illumination design and analysis software was used. The refractive indexes described below relating to the validation were values at the wavelength of 550 nm.

FIG. 4 is a cross-sectional view of a simulation model 110 used in the validation. In the validation, the model 110 includes a phosphor layer 31, a light-transmitting layer 32 disposed on the phosphor layer 31, and a polarizing layer 33 disposed on the light-transmitting layer 32.

In the model 110, the phosphor layer 31 has a square upper surface shape and each side having a length D₁ of 1000 μm. The phosphor layer 31 has a thickness T₁ of 100 μm, and a refractive index of 1.58. It is assumed that from the upper surface of the phosphor layer 31, a fluorescent light having a wavelength of 550 nm is uniformly scattered in an aspect of Lambert scattering.

In the model 110, the light-transmitting layer 32 has a shape of inverted truncated quadrangular pyramid similarly to the light-transmitting layer 14. In the model 110, the light-transmitting layer 32 is under three conditions of a thickness T₂ of 300 μm, 500 μm, and 1000 μm. The angle between the upper surface and the side surface of the light-transmitting layer 32 is assumed as an angle θ.

In the model 110 of the validation, the refractive index of the light-transmitting layer 32 is the highest in a columnar first area A1 including the center axis CL, and the refractive index is decremented from the first area A1 toward the outside by a predetermined width. Therefore, as indicated by the one-dot chain line in FIG. 4, the light-transmitting layer 32 is provided with a plurality of annular areas having an annular upper surface shape with a predetermined width (for example, 0.1 mm) around the first area A1. The number of the annular areas in FIG. 4 is only schematically illustrated, and the number of the actually formed annular areas is larger than the illustrated one.

In the model 110 of the validation, the refractive index is set to be same in each of the annular areas. In other words, in the model 110, the refractive index of the light-transmitting layer 32 is same from the upper surface to the lower surface of the light-transmitting layer 32. In the following description, an annular area that is positioned at an outermost periphery of the light-transmitting layer 32 and has the minimum refractive index is referred to as a second area A2.

In the light-transmitting layer 32 of the model 110, a refractive index n₁ in the first area A1 is set to be larger than the refractive index of the phosphor layer 31, and a refractive index n₂ in the second area A2 is set to be smaller than the refractive index of the phosphor layer 31. For example, in the light-transmitting layer 32, the refractive index n₁ of the first area A1 is set to 1.6 to 1.8, and the refractive index n₂ of the second area A2 is set to 1.3 to 1.5.

In the model 110, the polarizing layer 33 is a translucent plate-shaped body, and transmits the TM polarization component of the fluorescent light that has reached the polarizing layer 33 through the light-transmitting layer 32. The polarizing layer 33 reflects the component exceeding the critical angle of the TM polarization component and 90% of the TE polarization component of the fluorescent light, and absorbs 10% of the TE polarization component. The polarizing layer 33 has the refractive index of 1.51 and a thickness T₃ of 700 μm.

Here, two comparison models used as comparative examples in the validation are described. A first comparison model is a model without the light-transmitting layer 32 of the model 110. Specifically, the first comparison model is a model that includes only a phosphor layer 31 and a polarizing layer 33 having the mutually same size.

A second comparison model has the same configuration as the model 110, but is different from the model 110 in that the light-transmitting layer 32 has the uniform refractive index. Specifically, in the second comparison model, the light-transmitting layer 32 has the above-described refractive index n₂ as a whole.

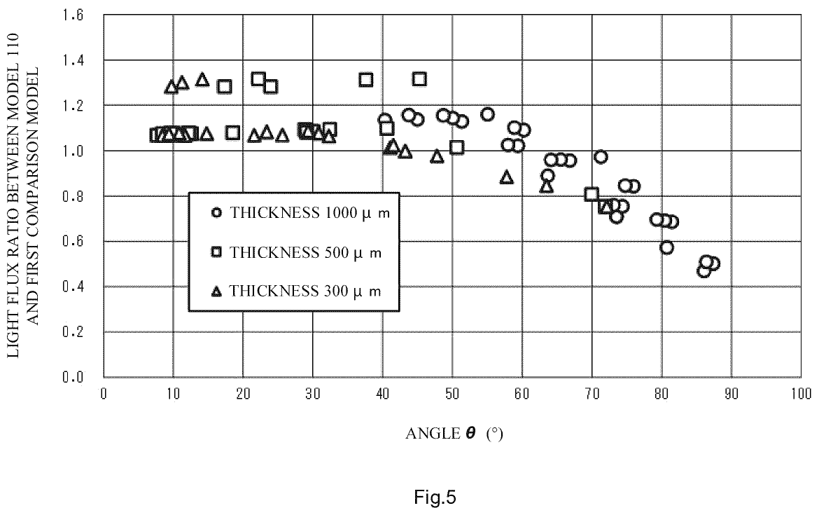

FIG. 5 is a graph illustrating a change of the light flux emitted from the upper surface of the polarizing layer 33 when the angle θ of the light-transmitting layer 32 of the above-described model 110 is changed. In FIG. 5, the horizontal axis indicates the angle θ, and the vertical axis indicates a ratio of the light flux of the model 110 to the light flux of the first comparison model.

From FIG. 5, it is seen that the more the angle θ increases, that is, the more the side surface of the light-transmitting layer 32 becomes perpendicular to the upper surface, the more the light flux ratio decreases. Especially, it is seen that when the thickness T₂ of the light-transmitting layer 32 is 1000 μm, the light flux ratio falls below 1.0 at the angle θ exceeding 60°.

From FIG. 5, it was confirmed that for the light-transmitting layer 32 of the model 110, when the angle θ is 10° or more and 60° or less, the maximum refractive index n₁ is 1.6 or more and 1.8 or less, the minimum refractive index n₂ is 1.3 or more and 1.5 or less, the pitch is 0.01 or more and 0.03 or less, and a light-transmitting layer thickness Z is 0.3 mm or more and 0.5 mm or less, the light flux mostly higher than that of the first comparison model is obtained.

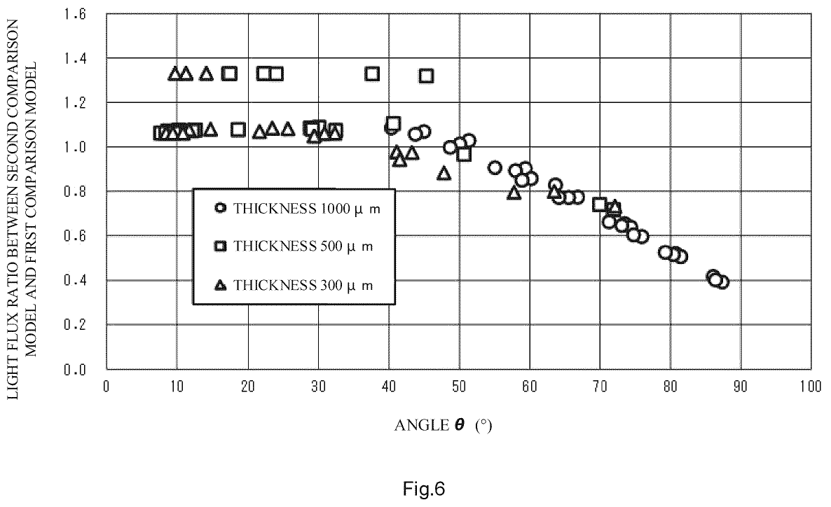

FIG. 6 is a graph illustrating a change of the light flux emitted from the upper surface of the polarizing layer 33 when the angle θ of the light-transmitting layer 32 of the above-described second comparison model is changed. In FIG. 6, the horizontal axis indicates the angle θ, and the vertical axis indicates a ratio of the light flux of the second comparison model to the light flux of the first comparison model.

From FIG. 6, it is seen that the more the angle θ increases, that is, the more the side surface of the light-transmitting layer 32 becomes perpendicular to the upper surface, the more the light flux ratio decreases. Especially, it is seen that when the thickness T₂ of the light-transmitting layer 32 is 1000 μm, the light flux ratio falls below 1.0 at the angle θ exceeding 50°.

From FIG. 6, also in the second comparison model, when the angle θ is 10° or more and 60° or less, the refractive index n₂ is 1.3 or more and 1.5 or less, and the light-transmitting layer thickness Z is 0.3 mm or more and 0.5 mm or less, the light flux mostly higher than that of the first comparison model was obtained. That is, it was confirmed that even when the refractive index distribution is not provided at the light-transmitting layer 32, when the refractive index of the light-transmitting layer 32 with the inclined side surface is smaller than the refractive index of the phosphor layer 31 and smaller than the refractive index of the light-transmitting substrate 27, the light flux higher than that of the first comparison model can be obtained.

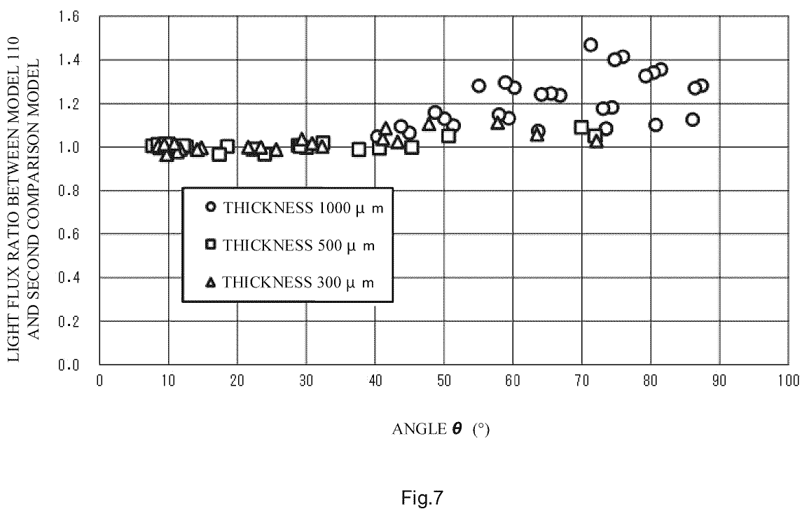

FIG. 7 is a graph illustrating a change of the light flux emitted from the upper surface of the polarizing layer 33 when the angle θ of the light-transmitting layer 32 of the above-described model 110 is changed. In FIG. 7, the horizontal axis indicates the angle θ, and the vertical axis indicates a ratio of the light flux of the model 110 to the light flux of the second comparison model.

From FIG. 7, the more the angle θ increases, that is, the more the side surface of the light-transmitting layer 32 becomes perpendicular to the upper surface, the more the light flux ratio increases. Especially, when the thickness T₂ of the light-transmitting layer 32 is 1000 μm, the light flux ratio is larger than 1.0 at the angle θ exceeding 40°.

From the above-described verification results, it is seen that when the light-transmitting layer 32 is provided with the refractive index distribution, from FIG. 5 and FIG. 7, the angle θ between the upper surface and the side surface of the light-transmitting layer 32 is preferably 60° or less, and especially, a range of from 40° to 60° is preferable. From FIG. 6 and FIG. 7, it is seen that when the light-transmitting layer 32 is not provided with the refractive index distribution, the angle θ is preferably 50° or less.

While the model 110 used in the validation is provided with the columnar first area A1 including the center axis CL of the light-transmitting layer 32 and a plurality of areas having the different refractive indexes with the predetermined width around the first area A1, and the refractive index decreases toward the outer periphery in the above-described aspect, the aspect of the refractive index distribution of the light-transmitting layer 32 is not limited to this. For example, the light-transmitting layer 32 only needs to be at least configured of the first area A1 and another area that is formed to surround the first area A1 and has the refractive index smaller than that of the first area A1.

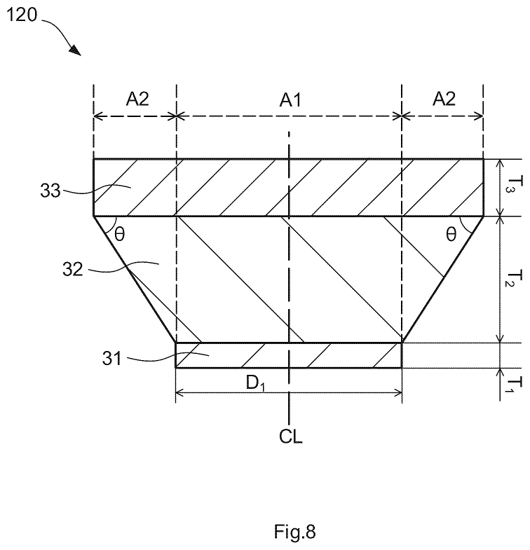

Specifically, for example, like a model 120 illustrated in FIG. 8 as a modification, the light-transmitting layer 32 may be separated into two of the columnar first area A1 that includes the center axis CL and has the maximum refractive index and the second area A2 that is a peripheral area of the first area A1 and has the minimum refractive index in an aspect. In the light-transmitting layer 32, the widths may be different between the respective areas like the light-transmitting layer 32 of the model 120 illustrated in FIG. 8.

While the refractive index is same in each of the plurality of areas having the different refractive indexes of the light-transmitting layer 32 in the aspect of the model 110 used in the validation, the refractive index distribution may be provided in each of the areas. That is, the refractive index distribution may be provided in the first area A1 and the second area A2. For example, in an aspect, the refractive index may decrease from the center of the first area Al toward the outer edge of the first area A1.

It is understood that the foregoing description and accompanying drawings set forth the preferred embodiments of the present invention at the present time. Various modifications, additions and alternative designs will, of course, become apparent to those skilled in the art in light of the foregoing teachings without departing from the spirit and scope of the disclosed invention. Thus, it should be appreciated that the present invention is not limited to the disclosed Examples but may be practiced within the full scope of the appended claims. The present application is based upon and claims the benefit of priority from the prior Japanese Patent Application No. 2024-009301 filed on Jan. 25, 2024, the entire contents of which are incorporated herein by reference.

### DESCRIPTION OF REFERENCE SIGNS

100 Light-emitting device
110 Model
11 Substrate structure
12 Light-emitting element
13, 31 Phosphor layer
14, 32 Light-transmitting layer
15 Wire grid portion
16 Covering member
21 Flat plate portion
22 Frame body portion
24 Semiconductor structure layer
25 Transparent substrate
27 Light-transmitting substrate
28 Wire grid
33 Polarizing layer

What is claimed is:

1. A light-emitting device comprising:
a light-emitting element including a semiconductor structure layer with a light-emitting layer;
a phosphor layer that is formed on the light-emitting element and contains a fluorescent substance, the fluorescent substance being excited by a light emitted from the light-emitting layer to emit a fluorescent light;
a translucent light-transmitting layer that is formed on the phosphor layer and has a side surface inclined outward toward an upper side; and
a wire grid portion that is formed on the light-transmitting layer and includes a translucent light-transmitting substrate and a wire grid, the wire grid including a plurality of linear metal bodies periodically arranged in a row on an upper surface of the light-transmitting substrate.

2. The light-emitting device according to claim 1, wherein
the light-transmitting layer has a refractive index that decreases toward the side surface of the light-transmitting layer.

3. The light-emitting device according to claim 2, wherein
the light-transmitting layer has the refractive index that decreases from a center axis passing through a center of the light-transmitting layer toward the side surface in a top view when the light-transmitting layer is viewed from above.

4. The light-emitting device according to claim 2, wherein
the light-transmitting layer has a first area that is formed from an upper surface to a lower surface inside the light-transmitting layer and has a highest refractive index in the light-transmitting layer, and a second area that is formed from an upper surface to a lower surface of the light-transmitting layer including a most outer peripheral side surface of the light-transmitting layer so as to surround the first area and has a smallest refractive index in the light-transmitting layer.

5. The light-emitting device according to claim 4, wherein
the refractive index of the first area of the light-transmitting layer is larger than a refractive index of the phosphor layer and a refractive index of the light-transmitting substrate of the wire grid portion.

6. The light-emitting device according to claim 5, wherein
the refractive index of the second area of the light-transmitting layer is smaller than the refractive index of the phosphor layer and the refractive index of the light-transmitting substrate of the wire grid portion.

7. The light-emitting device according to claim 3, wherein
the light-transmitting layer is a GRIN lens.

8. The light-emitting device according to claim 1, comprising
a covering member that continuously covers respective side surfaces of the light-emitting element, the phosphor layer, the light-transmitting layer, and the light-transmitting substrate and has a light reflectivity.
